(19) United States
(12) Patent Application Publication
(10) Pub. No.: US 2019/0360329 A1
(43) Pub. Date: Nov. 28, 2019

(54) A THROUGH BIT DIPOLE ACOUSTIC LOGGING TRANSMITTER AND A LOGGING DEVICE

(71) Applicant: Institute of Acoustics, Chinese Academy of Sciences, Beijing (CN)

(72) Inventors: Jiansheng CONG, Beijing (CN); Qian WEI, Beijing (CN); Chengxuan CHE, Beijing (CN); Xiuming WANG, Beijing (CN); Bin LIU, Beijing (CN)

(73) Assignee: Institute of Acoustics, Chinese Academy of Sciences, Beijing (CN)

(21) Appl. No.: 16/078,146

(22) PCT Filed: Jan. 4, 2018
(86) PCT No.: PCT/CN2018/071365

§ 371 Date: Aug. 21, 2018

(30) Foreign Application Priority Data
Apr. 1, 2017 (CN) 201710214045.2

(51) Int. Cl. E21B 49/00; B06B 1/06; G01V 1/02

(52) U.S. Cl. CPC E21B 49/00; B06B 1/0603; H01L 41/1876; B06B 2201/73; G01V 1/159

(57) ABSTRACT

The invention relates to a transmitter of a through bit dipole acoustic logging device and the logging device, and the transmitter includes a substrate and 2 piezoelectric ceramic plates respectively at either sides of the substrate; wherein the piezoelectric ceramic plate is composed of at least one block of piezoelectric ceramic units; wherein the lengthwise direction of the piezoelectric ceramic elements is along the width direction of the piezoelectric ceramic plates, the width direction of the piezoelectric ceramic units is along the thickness direction of the piezoelectric ceramic plates, and the thickness direction of the piezoelectric ceramic units is along the lengthwise direction of the piezoelectric ceramic plates; the polarization directions of the piezoelectric ceramic units are along the thickness direction of the piezoelectric ceramic units; when electric excitation is applied along the length of the piezoelectric ceramic plate, the piezoelectric ceramic plate on one side of the substrate is extended while the piezoelectric ceramic plate of the other side shortened, pushing the substrate to form a bending vibration, transmitting the thrust to the media and generating acoustic waves.

### BACKGROUND OF THE INVENTION

### Technical Field

The present invention relates to the field of mineral resources exploration and development technology, especially to the field of mine geophysical (logging) technology, drilling measurement technology and measurement while drilling technology, and more particularly to a through bit dipole acoustic logging transmitter and logging device.

### Description of Related Art

The evaluation of the formation before and after hydraulic fracturing for the larger horizontal well (e.g. more than 1000 m) is the hotspot, difficulty and key technology of the shale gas development in China. The through bit cross-dipole acoustic logging technology is the preferred method of measurement to solve such problem by far.

The through bit logging is a new technology developed in recent years. The through bit logging refers to a way in which the logging instrument passes through the drill bit of special mechanical design and enters the measurement section for logging data acquisition. The through bit logging technology has its unique advantages, mainly including the following: \textcircled{1} Reducing engineering risks from drilling operations, because in most of the operation time the logging instruments are placed in the drill pipe so as to be protected; \textcircled{2} Saving operating time significantly. The through bit logging is able to carry out logging operations without the need for taking the drilling tool out of the ground, which saves the well-completion practice time greatly compared with the wireline logging, which should be performed after taking the drilling tool out. \textcircled{3} Obtaining continuous and reliable logging data. The through bit logging is the way that the logging instruments assembly passes through the drill pipe to measure the target formation when the drill bit and the drill pipe stop vibrating. Therefore, the quality of the data obtained is stable and reliable. \textcircled{4} Performing survey logging. The through bit logging is able to enter the open hole section to measure without taking the drill out and obtain a variety of important information of the reservoir for guiding the continued drilling, and providing physical basis for scientific drilling.

The through bit logging requires the logging instrument with small outside diameter, which is 54 mm at present, mainly including natural gamma, well temperature, induction resistivity, natural potential, formation density, well diameter, neutron porosity and monopole interval transit time logging. The through bit logging technology is suitable for harsh well conditions, such as horizontal well, high angle deviated well, wellbore collapse and shale expansion. Measurement in the North Sea exploratory well and evaluation well, has overcome the problems that the conventional wireline logging encountered, and obtained high-quality logging data.

The through bit monopole interval transit time instrument is used mainly for the shear wave and longitudinal wave velocity measurement. The rock properties, including Poisson's ratio, static Young's modulus and minimum horizontal stress gradient, can be calculated with the longitudinal wave velocity and shear wave velocity recorded by array receivers on the monopole acoustic logging instrument, combined with the density logging information. The stress data calculated above and the quality parameters being able to reflect the reservoir quality (e.g. clay content and porosity) are useful for selecting the best hydraulic fracturing effect formation. However, the monopole acoustic logging instrument cannot measure the shear wave velocity of the formation in the soft and ultra-soft formation, and therefore cannot get the properties of the rock, which is mainly caused by the symmetric monopole acoustic source. The main solution to such problem is to use a dipole transducer and a cross-dipole transducer as a transmit transducer to measure the shear wave velocity of the formation. However, there have been few public reports on the commercial use of through bit cross-dipole acoustic logging instrument.

At present, the outer diameter of the conventional dipole acoustic wireline logging instrument is 90 mm, and there are two main kinds of transducers (also known as transmitters), one of which is an electromagnetic type dipole acoustic transducer, and the other is a piezoelectric transducer type usually working in bending vibration mode with laminated-type. In general, the laminated-type bending vibration piezoelectric transducer is made of piezoelectric ceramic plates polarized in the thickness direction and a metal aluminum substrate by means of bonding. As the outer diameter of the through bit instrument is very small (54 mm), the geometrical dimensions of the piezoelectric crystals and the substrate of the bending vibrator with laminated structure are correspondingly reduced such that the radiating surface of the bending vibrator is narrowed after the assembly of the cross-dipole transducer compared with the conventional cross-dipole acoustic logging instrument, resulting in the weakening of the excitation energy of the transducer and the lowering of the signal-to-noise ratio.

### BRIEF SUMMARY OF THE INVENTION

The purpose of the invention is to provide a transmitter of a through bit dipole acoustic logging device and the logging device comprising the same against the shortcomings of the prior art, mainly the structure design of the acoustic transmitter and its logging device, which can meet the acoustic performance requirements of the small diameter cross-dipole acoustic logging transmitter under the conditions of satisfying the mechanical requirements of the through bit logging instrument.

To solve the above problems, in the first aspect, the invention provides a transmitter of a through bit dipole acoustic logging device, and the transmitter includes a substrate and at least 2 piezoelectric ceramic plates respectively on either side of the substrate; wherein the piezoelectric ceramic plate is composed of at least one block of piezoelectric ceramic units; wherein the lengthwise direction of the piezoelectric ceramic units is along the width direction of the piezoelectric ceramic plate, the width direction of the piezoelectric ceramic units is along the thickness direction of the piezoelectric ceramic plate, and the thickness direction of the piezoelectric ceramic units is along the lengthwise direction of the piezoelectric ceramic plate; the polarization directions of the piezoelectric ceramic units are along the thickness direction of the piezoelectric ceramic plates; when electric excitation is applied along the length of the piezoelectric ceramic plate, the piezoelectric ceramic plate on one side of the substrate is extended while the piezoelectric ceramic plate of the other side shortened, pushing the substrate to form a bending vibration, transmitting the thrust to the media and generating acoustic waves.

Preferably, each of the piezoelectric ceramic plates is composed of 2n blocks of piezoelectric ceramic units, every two adjacent piezoelectric ceramic units of the 2n blocks of piezoelectric ceramic units belonging to the same plate are polarized in opposite direction, the 2n blocks of piezoelectric ceramic units belonging to the same plate are connected in parallel; wherein n is a natural number.

Preferably, the substrate is provided with through-holes at both ends along the length direction, and is fixed via fixed part through the through-hole to the though bit dipole acoustic logging device.

It is further preferred that the piezoelectric ceramic plate is formed by bonding the2n blocks of piezoelectric ceramic units with an adhesive.

It is further preferred that the adhesive is an epoxy resin.

Preferably, the piezoelectric ceramic plates and the substrate are bonded with an adhesive.

It is further preferred that the adhesive is an epoxy resin.

Preferably, the substrate can be titanium, copper, aluminum, low expansion alloy, or composite materials.

Preferably, the material of the piezoelectric ceramic plate is PZT4, PZT5 or PZT8.

Preferably, the electrodes in the same position on both sides of the substrate are connected in the identical way, but the polarization of the piezoelectric ceramic units in the same position on both sides is the opposite.

Preferably, the electrodes in the same position on both sides of the substrate are connected in the opposite way, but the piezoelectric ceramic units in the same position on both sides are polarized in the identical way.

In the second aspect, the invention also provides a through bit dipole acoustic logging device including the transmitter of the first aspect.

Compared with the conventional laminated-type dipole transmitters, the design of the segmented dipole transmitter of the invention can increase the bending deformation of the transmitter, increase the outward thrust from the transmitter surface, and thereby increase the transmitting energy of the transmitter; the invention can realize the transmission of the lower frequency acoustic wave in the limited space, and is more suitable for the shear wave measurement in the soft formation and even the ultra-soft formation.

### BRIEF DESCRIPTION OF THE SEVERAL VIEWS OF THE DRAWINGS

Hereinafter, an embodiment of the invention will be described in detail with reference to the accompanying drawings, in which:

FIG. 1 is a schematic diagram of the acoustic measurement;

FIG. 2 is a schematic top view of a dipole transmitter provided by the present embodiment;

FIG. 3 is the first schematic diagram of a longitudinal section of a dipole transmitter provided by the embodiment of the invention;

FIG. 4 is the second schematic diagram of a longitudinal section of a dipole transmitter provided by the embodiment of the invention;

FIG. 5 is the third schematic diagram of a longitudinal section of a dipole transmitter provided by the embodiment of the invention;

FIG. 6 is the conductance-frequency curve comparison of two transmitters in the frequency range of 40˜5000 Hz;

FIG. 7 is the conductance-frequency curve comparison of two transmitters in the frequency range of 500˜1000 Hz;

FIG. 8 is the conductance-frequency curve comparison of two transmitters in the frequency range of 2000˜3000 Hz;

FIG. 9 is a stereoscopic view of a dipole transmitter provided by the present embodiment.

### DETAILED DESCRIPTION OF THE INVENTION

The present invention will be further described hereinafter with drawings and specific embodiments, but it should be understood that these embodiments are for illustrative purposes only, and should not be construed as limiting the invention in any form, that is, it is not intended to limit the protection scope of the invention.

In an embodiment of the present invention, a transmitter of a through bit dipole acoustic logging device and a related through bit dipole acoustic logging device are provided. The transmitter includes a substrate, at both sides of which at least 2 piezoelectric ceramic plates are symmetrically disposed; wherein each of the piezoelectric ceramic plates is composed of at least one piezoelectric ceramic units. The lengthwise direction of the piezoelectric ceramic elements is along the width direction of the piezoelectric ceramic plates, the width direction of the piezoelectric ceramic units is along the thickness direction of the piezoelectric ceramic plates, and the thickness direction of the piezoelectric ceramic units is along the lengthwise direction of the piezoelectric ceramic plates. The polarization direction is along the thickness direction of the piezoelectric ceramic units. During operations, the piezoelectric ceramic plate on one side of the substrate is extended while the piezoelectric ceramic plate of the other side shortened, pushing the substrate to form a bending vibration, transmitting the thrust to the media and generating acoustic waves. The piezoelectric ceramic units may be the same, and may be of different sizes and shapes.

The piezoelectric ceramic plate may be composed of 2n piezoelectric ceramic units, wherein n is natural number. In an example, adjacent units of the 2n piezoelectric ceramic units on the same side of substrate are polarized in an opposite way while their respective electrodes are connected in parallel; in this way, the electric capacity and charge amount of each of the piezoelectric ceramic plates are equivalent to 2n times the electric capacity of each piezoelectric ceramic unit, thereby the overall performance of the transducer according to the embodiment of the present invention can be improved. Of course, other methods can be taken, for example, 2n adjacent piezoelectric ceramic cells in the same side of the piezoelectric ceramic plate may have the same polarization direction, while the respective electrodes are connected in series.

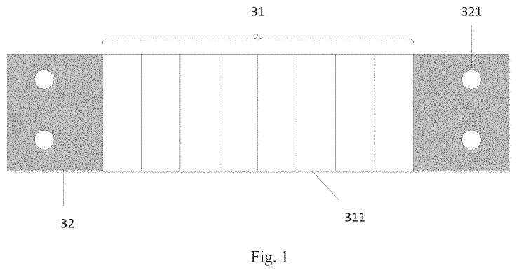

FIG. 1 is a schematic diagram of the acoustic measurement provided by the embodiment of the invention. As shown in FIG. 1, the logging device 1 is located in a wellbore 9 filled with slurry 7 media, and a formation 8 is outside the wellbore 9. Wherein the logging device 1 includes a transmitting circuit 2, a transmitter 3, an acoustic insulator 4, a receiver array 5 and a receiving circuit 6. During operations, the logging device 1 is connected with a cable 10, and an electrical signal is generated by the transmitting circuit 2 such that the transmitter 3 generates acoustic waves which pass through the slurry 7 media to reach the formation 8 and then spread in the formation 8. The acoustic signal with the information of the formation 8 is then converted into an electrical signal by the receiver array 5 and then the formation is evaluated according to the received electrical signal. The acoustic transmission process is shown by the arrow in FIG. 1.

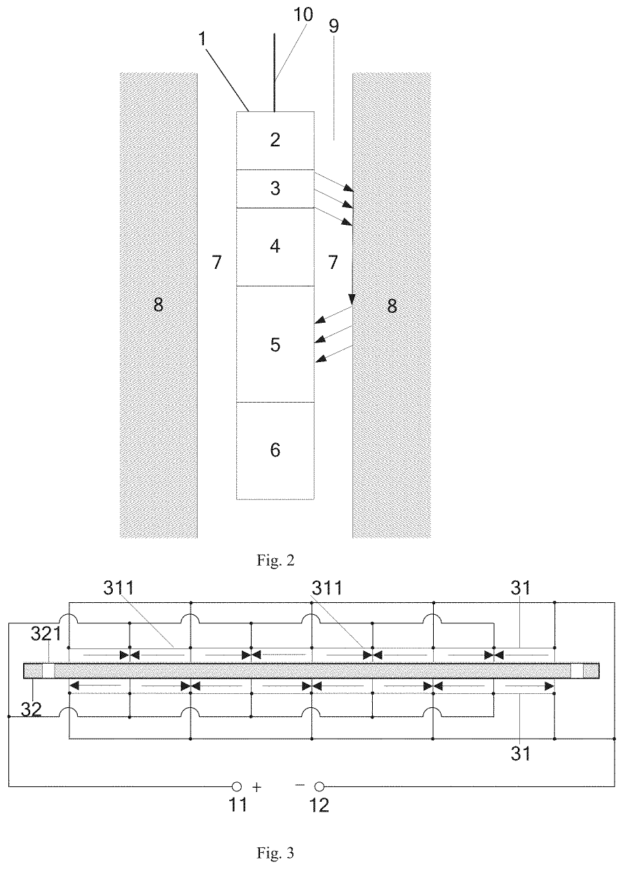

FIG. 2 is a schematic top view of a dipole transmitter provided by the embodiment of the invention. FIG. 9 is a stereoscopic view of the dipole transmitter. The structure and function of the dipole emitter according to the embodiments of the invention are illustrated in combination with FIG. 2 and FIG. 9.

As shown in FIG. 2, the transmitter of the embodiment includes: a substrate 32 and two piezoelectric ceramic plates 31, each of the two plates are located on each side of the substrate 32 (FIG. 2 schematically illustrates only a piezoelectric ceramic plate 31 on the front side, another piezoelectric ceramic plate 31 on the opposite side being of the same size can be visible from the FIG. 8). Each piezoelectric ceramic plate 31 may consist of 2n pieces of piezoelectric ceramic unit 311, wherein n is the natural number.

Through holes 321 may be provided at both ends of the substrate, and the substrate 32 is fixed to the through bit dipole acoustic logging device 1 with fixing parts passing through the through holes 321.

In particular, for each piece of piezoelectric ceramic plate, it may be made of 2n piezoelectric ceramic rectangular columns which are spliced and adhered together, and each piezoelectric ceramic rectangular column is called a piezoelectric ceramic unit. The lengthwise direction of the piezoelectric ceramic elements is along the width direction of the piezoelectric ceramic plates, the width direction of the piezoelectric ceramic units is along the thickness direction of the piezoelectric ceramic plates, and the thickness direction of the piezoelectric ceramic units is along the lengthwise direction of the piezoelectric ceramic plates.

Therefore, each piece of piezoelectric ceramic plate is equivalent to a piezoelectric ceramic stack composed of a plurality of piezoelectric ceramic units; the polarization direction is along the thickness direction of the piezoelectric ceramic units (the lengthwise direction of the piezoelectric ceramic plate), and the polarization directions of every two adjacent piezoelectric ceramic units are opposite, and the electrode connection mode of the 2n piezoelectric ceramic units is a parallel connection. When an external electric signal is applied, the adjacent piezoelectric ceramic units may be simultaneously elongated (or shortened) in the thickness direction (the piezoelectric ceramic plate is elongated (or shortened) in the lengthwise direction); if a stress is pre-applied along the length of the piezoelectric ceramic plate, the piezoelectric ceramic plate will be elongated (or shortened) in the direction of length.

During operations, the piezoelectric ceramic plates on both sides of the substrate are electrically stimulated along the length of the piezoelectric ceramic plates. At a time, the piezoelectric ceramic plate 31 on one side of the substrate 32 is extended while the piezoelectric ceramic plate 31 of the other side shortened, pushing the substrate 32 to form a bending vibration, transmitting the thrust to the media and generating acoustic waves. One explanation is that the acoustic wave vibrates along radial direction of the borehole, propagates along the axial direction of the borehole, and generates a bending vibration down the borehole, from which the dipole wave velocity could be obtained approximately in the formation.

In order to realize the elongating or shortening at different directions of piezoelectric ceramic plate 31 at different sides, it is necessary to reasonably distribute the polarization directions of the piezoelectric ceramic units and the connection modes of the electrodes. FIG. 3 shows the polarization direction and the electrode connection of piezoelectric ceramic units, in which the arrow direction is the polarization direction of the piezoelectric ceramic unit 311. As shown, the electrodes on the two sides of the substrate are connected in the same way, but the piezoelectric ceramic units on both sides are polarized in an opposite way. In this way, when the piezoelectric ceramic plate on one side is elongated, the piezoelectric ceramic plate on the other side is shortened.

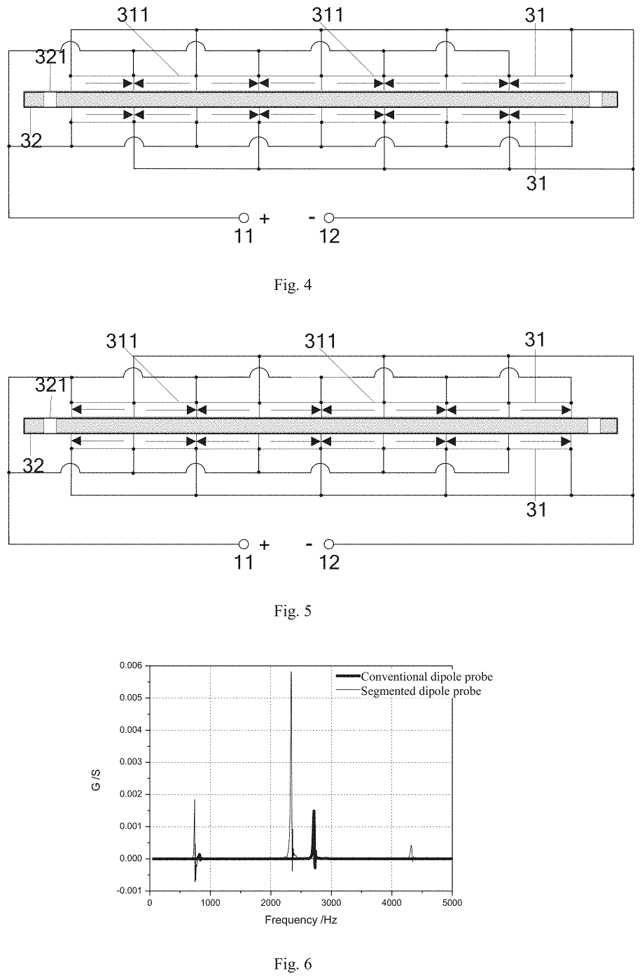

FIG. 4 and FIG. 5 shows another kind of polarization direction and electrode connection of piezoelectric ceramic units. In the second option, the electrodes on both sides of the substrate are connected in the opposite way, but the piezoelectric ceramic units on both sides are polarized in the same way. In this way, when the piezoelectric ceramic plate on one side is elongated, the piezoelectric ceramic plate on the other side is shortened.

Certainly, those skilled in the art may realize that other connection patterns beyond that in FIG. 3, FIG. 4 and FIG. 5 can also be chosen.

It is to be noted that 2n piezoelectric ceramic plates 31 may be uniformly distributed on both sides of the substrate 32, as shown in FIGS. 3, 4 and 5, and two piezoelectric ceramic plates on both sides of the substrate are composed of for example eight piezoelectric ceramic units, respectively. Wherein the piezoelectric ceramic plate is generally fixed to the logging device 1 with a screw passing through the through hole 321 during the actual operations, and in general, the through holes are preferably provided on both ends of the substrate in the longitudinal direction, and the shape and quantity are set according to the specific situations, of which the shape is preferably round, and the quantity is generally four, but not limited to four.

In one example, the substrate 32 is generally a metal material such as titanium, copper, aluminum, low expansion alloy, or composite materials.

In another example, the piezoelectric ceramic plate 31 is made of the piezoelectric ceramic units 311 by means of bonding with an adhesive. The adhesive is preferably a polymer material such as an epoxy resin, but it is not limited to such an adhesive. Preferably, the piezoelectric ceramic plate 31 and the substrate 32 are bonded with an adhesive. It is further preferred that the adhesive is a polymer material such as an epoxy resin, but it is not limited to such an adhesive.

In yet another example, the piezoelectric ceramic plate material is PZT4, PZT5 or PZT8, but it is not limited to these types of piezoelectric ceramic materials.

Since the piezoelectric ceramic plate 31 adopts multi-segmented piezoelectric ceramic elements, the dipole emitter in the embodiment of the invention may be referred as a segmented dipole emitter. The outward thrust generated by the segmented dipole transmitter is not only related to the size parameters of the transmitter, but also to the parameters of the piezoelectric ceramic material, especially to d33 piezoelectric constant.

Conventional laminated type dipole transmitters is also composed of a substrate and piezoelectric ceramic plates on both sides of the substrate. When applying electric excitation to the piezoelectric ceramic plates, the piezoelectric ceramic plate at one side elongates in the length direction while the piezoelectric ceramic plate at the other side shortens in the length direction, therefore the emitter develops an overall bending vibration.

Conventional laminated type dipole transmitters differs from the segmented dipole transmitters according to the embodiments of the present invention in that, in the conventional type laminated dipole transmitters, piezoelectric ceramic plate is a solid block of piezoelectric material, the polarization direction being along the thickness direction of the piezoelectric ceramic plate. With respect to conventional laminated dipole emitter, the outward thrust generated by bending vibration is not only related to the size parameters of the transmitter, but also related to parameters of piezoelectric ceramic materials, especially the d31 piezoelectric constant.

The type of piezoelectric ceramic material used in the transmitter is an emissive PZT4 of which the value of a d33 piezoelectric constant is more than twice the d31 piezoelectric constant. For transmitters of the same geometric dimensioning, the segmented transmitter should be superior to the conventional type in performance. In through bit acoustic logging, a small-diameter instrument requires a narrowing of the radiation surface of the transmitter; however, in the case where the radiation surface is narrowed, the radiation energy of the conventional transmitter will decrease, however the segmented transmitter can meet the logging requirements.

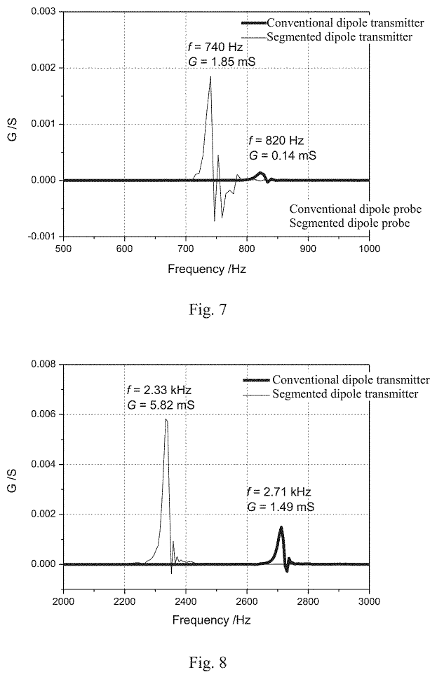

In order to highlight the application advantages of the segmented dipole transmitter of the invention in the logging, the admittance properties of the conventional and the segmented dipole transmitters are measured in the free state of air, and in the figures, the thick line represents the conventional dipole transmitter, and the thin line represents the segmented dipole transmitter. FIG. 6 is the conductance-frequency curve comparison of the two transmitters in the frequency range of 40˜5000 Hz, and as can be seen from the figure, the segmented dipole transmitter has a lower resonant frequency and a higher conductance peak. FIG. 7 is the conductance-frequency curve comparison of two transmitters in the frequency range of 500˜1000 Hz, and as can be seen from the figure, the resonant frequency of the segmented dipole transmitter is reduced by 80 Hz compared to the conventional dipole transmitter, while the conductance peak is about 13 times that of the conventional dipole transmitter. FIG. 8 is the conductance-frequency curve comparison of two transmitters in the frequency range of 2000˜3000 Hz, and as can be seen from the figure, the resonant frequency of the segmented dipole transmitter is reduced by 380 Hz compared to the conventional dipole transmitter, while the conductance peak is about 4 times that of the conventional dipole transmitter.

As can be seen from the comparison of the measurement results in FIGS. 6 to 8, the segmented dipole transmitter in the invention has the features of low frequency and high power transmission, and is suitable for the transducer in the through bit and small diameter acoustic logging, more particularly for the shear wave measurement in the soft formation and even the ultra-soft formation.

The cross-dipole acoustic data can be used to determine the shear wave circumferential anisotropy features, and further obtain the anisotropy information of the formation around the borehole wall, and it has a wide range of applications especially in the study of stratigraphic fracture features and the geostress measurement.

Although the invention has been described to some extent, it will be apparent that various appropriate changes for each condition may be made without departing from the spirit and scope of the invention. It is to be understood that the invention is not limited to the described embodiments, and is within the scope of the claims, including the equivalent of each factor described above.

In the specific embodiments described above, the purpose, technical scheme and advantageous effects of the invention are described in further detail, and it is to be understood that the above description is merely a specific embodiment of the invention, and is not intended to limit the scope of protection of the invention, and any modifications, equivalents, improvements and the like within the spirit and principles of the invention should be contained in the protection scope of the invention.

1. A transmitter of a through bit dipole acoustic logging device, characterized in that, the transmitter includes a substrate and at least 2 piezoelectric ceramic plates respectively at either sides of the substrate; wherein
the piezoelectric ceramic plate is composed of at least one blocks of piezoelectric ceramic units; wherein the lengthwise direction of the piezoelectric ceramic units is along the width direction of the piezoelectric ceramic plate, the width direction of the piezoelectric ceramic units is along the thickness direction of the piezoelectric ceramic plate, and the thickness direction of the piezoelectric ceramic units is along the lengthwise direction of the piezoelectric ceramic plate; the polarization directions of the piezoelectric ceramic units are along the thickness direction of the piezoelectric ceramic units;
when electric excitation is applied along the length of the piezoelectric ceramic plate, the piezoelectric ceramic plate on one side of the substrate is extended while the piezoelectric ceramic plate of the other side shortened, pushing the substrate to form a bending vibration, transmitting the thrust to the media and generating acoustic waves.

2. The transmitter of claim 1, characterized in that, each of the piezoelectric ceramic plates is composed of 2n blocks of piezoelectric ceramic units, every adjacent two piezoelectric ceramic units of the 2n blocks of piezoelectric ceramic units belonging to the same plate are polarized in an opposite way, the 2n blocks of piezoelectric ceramic units belonging to the same plate are connected in parallel; wherein n is a natural number.

3. The transmitter of claim 1, characterized in that, the substrate is provided with through-holes along the length direction, and is fixed via fixed part through the through-hole to the though bit dipole acoustic logging device.

4. The transmitter of claim 1, characterized in that, the piezoelectric ceramic plate is formed by bonding the piezoelectric ceramic units with an adhesive.

5. The transmitter of claim 4, characterized in that, the adhesive is an epoxy resin.

6. The transmitter of claim 1, characterized in that, the piezoelectric ceramic plate and the substrate are bonded with an adhesive.

7. The transmitter of claim 6, characterized in that, the adhesive is an epoxy resin.

8. The transmitter of claim 1, characterized in that, the substrate is titanium, copper, aluminum, low expansion alloy or composite materials.

9. The transmitter of claim 1, characterized in that, the material of the piezoelectric ceramic plate is PZT4, PZT5 or PZT8.

10. The transmitter of claim 1, characterized in that, the electrodes in the same position on both sides of the substrate are connected in completely identical way, but the polarization of the piezoelectric ceramic units in the same position on both sides is the opposite.

11. The transmitter of claim 1, characterized in that the electrodes in the same position on both sides of the substrate are connected in the opposite way, but the piezoelectric ceramic elements in the same position on both sides are polarized in the same direction.

12. A through bit dipole acoustic logging device including the transmitter of claim 1.

13. A through bit dipole acoustic logging device including the transmitter of claim 2.

14. A through bit dipole acoustic logging device including the transmitter of claim 3.

15. A through bit dipole acoustic logging device including the transmitter of claim 4.

16. A through bit dipole acoustic logging device including the transmitter of claim 5.

17. A through bit dipole acoustic logging device including the transmitter of claim 6.

18. A through bit dipole acoustic logging device including the transmitter of claim 7.

19. A through bit dipole acoustic logging device including the transmitter of claim 8.

20. A through bit dipole acoustic logging device including the transmitter of claim 9.
